(19) United States
(12) Patent Application Publication
(10) Pub. No.: US 2025/0391735 A1
(43) Pub. Date: Dec. 25, 2025

(54) SEMICONDUCTOR PACKAGE INCLUDING A HEAT-DISSIPATION MEMBER AND A HEAT-DISSIPATION PIPE AND SEMICONDUCTOR PACKAGE MODULE INCLUDING THE SAME

(71) Applicant: SAMSUNG ELECTRONICS CO., LTD., SUWON-SI (KR)

(72) Inventors: Sounguk KIM, Suwon-si (KR); Yeonghyeon GIM, Suwon-si (KR); Minwoo CHO, Suwon-si (KR)

(21) Appl. No.: 18/973,202

(22) Filed: Dec. 9, 2024

(30) Foreign Application Priority Data
Jun. 21, 2024 (KR) 10-2024-0081104

(51) Int. Cl. H01L 23/427; H01L 23/00

(52) U.S. Cl. CPC H01L 23/427; H01L 24/29; H01L 2224/29187; H01L 2224/2919

(57) ABSTRACT

A semiconductor package includes: a package substrate; a semiconductor chip disposed on the package substrate; and a heat-dissipation member disposed on the package substrate, wherein the heat-dissipation member includes a heat-dissipation pipe. The heat-dissipation member has a first region and a second region. The first region is placed on the semiconductor chip. The second region is placed on an edge region of the package substrate. The first region has a first thickness. The second region has a second thickness. The second thickness is different from the first thickness. The heat-dissipation pipe is provided in the second region and faces at least one side surface of the semiconductor chip.

### CROSS-REFERENCE TO RELATED APPLICATION

This U.S. non-provisional patent application claims priority under 35 U.S.C. § 119 to Korean Patent Application No. 10-2024-0081104, filed on Jun. 21, 2024, in the Korean Intellectual Property Office, the disclosure of which is incorporated by reference herein in its entirety.

### TECHNICAL FIELD

Embodiments of the present inventive concept relate to a semiconductor package, and in particular, to a semiconductor package including a heat-dissipation member and a heat-dissipation pipe.

### DISCUSSION OF THE RELATED ART

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB by bonding wires or bumps. As the electronics industry continues to further develop, semiconductor package technology is under development in various ways with the goals of miniaturization, weight reduction, and manufacturing cost reduction. Furthermore, as the utilization of this technology expands into different fields, including mass storage devices, several types of semiconductor packages are emerging. For example, as the semiconductor device consumes more electric power for high speed processing and for more storage capacity, the desirability of regulating heat within the semiconductor package increases.

### SUMMARY

According to an embodiment of the present inventive concept, a semiconductor package includes: a package substrate; a semiconductor chip disposed on the package substrate; and a heat-dissipation member disposed on the package substrate, wherein the heat-dissipation member includes a heat-dissipation pipe. The heat-dissipation member has a first region and a second region. The first region is placed on the semiconductor chip. The second region is placed on an edge region of the package substrate. The first region has a first thickness. The second region has a second thickness, and the second thickness is different from the first thickness. The heat-dissipation pipe is provided in the second region and faces at least one side surface of the semiconductor chip.

According to an embodiment of the present inventive concept, a semiconductor package includes: a package substrate; a semiconductor chip disposed on the package substrate; a heat-dissipation member disposed on the package substrate, wherein the heat-dissipation member has a cavity; and a heat conduction layer disposed on the semiconductor chip, wherein the semiconductor chip and the heat conduction layer are disposed in the cavity. The heat-dissipation member includes a heat-dissipation pipe. When viewed in a plan view, the heat-dissipation pipe includes: a body portion having a ‘U’-shape; and an injection portion connected to an end of the body portion, wherein the body portion at least partially encloses the semiconductor chip.

According to an embodiment of the present inventive concept, a semiconductor package module includes: a plurality of semiconductor packages and a connection pipe, wherein each of the semiconductor packages includes: a package substrate; a semiconductor chip disposed on the package substrate; a heat-dissipation member disposed on the package substrate; and a heat conduction layer disposed on the semiconductor chip, wherein the heat-dissipation member includes a heat-dissipation pipe provided in the heat-dissipation member. The heat conduction layer is in contact with the heat-dissipation member. The semiconductor chip has four side surfaces. The heat-dissipation pipe is configured to allow a refrigerant to pass therethrough and to extend along three of the four side surfaces of the semiconductor chip. The connection pipe is connected to an end of the heat-dissipation pipe, and the semiconductor packages are connected to each other through the connection pipe.

### BRIEF DESCRIPTION OF THE DRAWINGS

FIG. 1 is a diagram schematically illustrating an operation cycle of a refrigeration apparatus according to an embodiment of the present inventive concept.

FIG. 2 is a plan view illustrating a unit semiconductor package according to an embodiment of the present inventive concept.

FIG. 3 is a cross-sectional view, which is taken along a line A-A′ of FIG. 2 to illustrate a unit semiconductor package according to an embodiment of the present inventive concept.

FIG. 4A is a perspective view illustrating a semiconductor package module according to an embodiment of the present inventive concept.

FIG. 4B is a plan view illustrating a semiconductor package module according to an embodiment of the present inventive concept.

FIGS. 5, 6, and 7 are cross-sectional views illustrating a process of fabricating a unit semiconductor package, according to an embodiment of the present inventive concept.

FIGS. 8 and 9 are cross-sectional views illustrating a process of fabricating a semiconductor package module, according to an embodiment of the present inventive concept.

FIG. 10 is a cross-sectional view illustrating a process of fabricating a semiconductor package module, according to an embodiment of the present inventive concept.

### DETAILED DESCRIPTION OF THE EMBODIMENTS

Example embodiments of the present inventive concept will now be described more fully with reference to the accompanying drawings, in which example embodiments are shown. In the figures, like reference numerals may denote like elements or features, and thus their descriptions may be omitted.

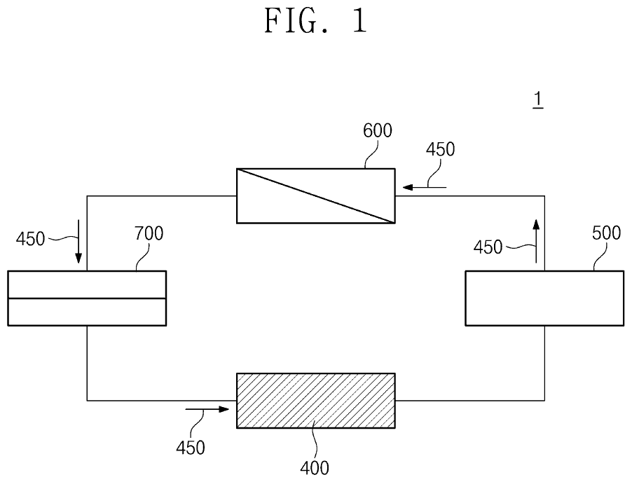

FIG. 1 is a diagram schematically illustrating an operation cycle of a refrigeration apparatus 1 according to an embodiment of the present inventive concept.

Referring to FIG. 1, a refrigeration apparatus 1 may include a compressor 500, a condenser 600, an expansion valve 700, an evaporator 400, and a refrigerant 450 passing through them.

For example, the compressor 500 may be configured to compress the refrigerant 450, thereby allowing the refrigerant 450 to reach a high-temperature and high-pressure gaseous state. The condenser 600 may be configured to condense and liquefy the refrigerant 450, which has passed through the compressor 500 and are in a high-temperature and high-pressure gaseous state. The expansion valve 700 may be configured to expand the refrigerant 450 that is liquefied by the condenser 600, thereby lowering the temperature of the refrigerant 450. For example, the expansion value 700 may decrease the pressure of the refrigerant 450. When the refrigerant 450 is ejected from the expansion valve 700, the refrigerant 450 may be in a low-temperature and low-pressure liquid state. The evaporator 400 may be configured to evaporate the refrigerant 450 that is ejected from the expansion valve 700, thereby allowing the refrigerant 450 to reach a gaseous state. The refrigerant 450 that is evaporated by the evaporator 400 may pass through the compressor 500, the condenser 600, the expansion valve 700, and the evaporator 400, and these processes may be repeatedly executed.

In the refrigeration apparatus 1, the refrigerant 450 may be liquefied and evaporated while being circulated through the compressor 500, the condenser 600, the expansion valve 700, and the evaporator 400, and for example, the refrigerant 450 may lose its heat energy during the evaporation process, thereby enabling the refrigeration apparatus 1 to function as a cooling machine.

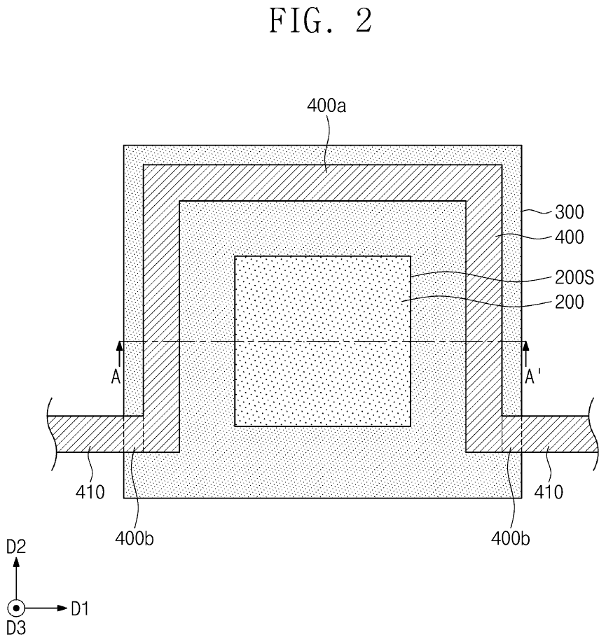

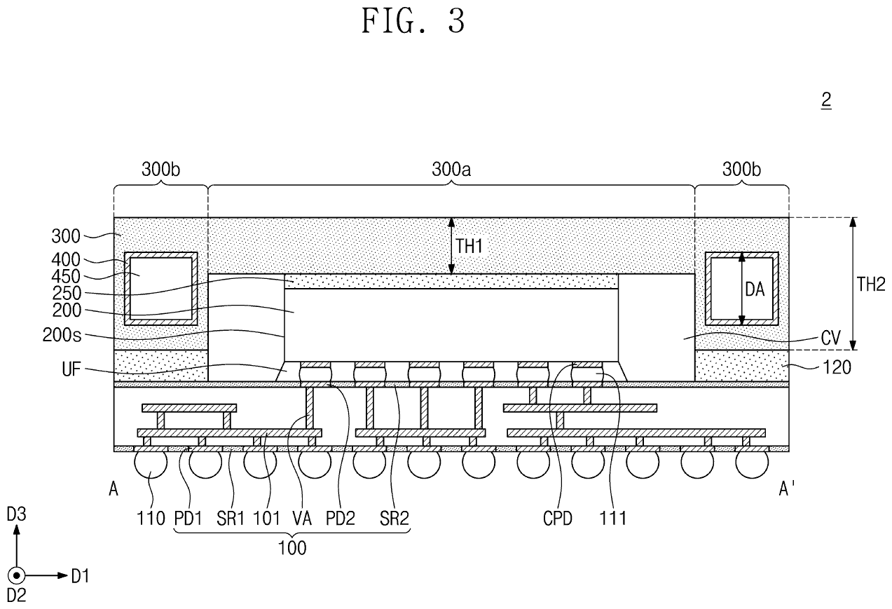

FIG. 2 is a plan view illustrating a unit semiconductor package according to an embodiment of the present inventive concept. FIG. 3 is a cross-sectional view, which is taken along a line A-A′ of FIG. 2 to illustrate a unit semiconductor package according to an embodiment of the present inventive concept.

Referring to FIGS. 2 and 3, a unit semiconductor package 2 may include a package substrate 100, an adhesive pattern 120, a semiconductor chip 200, a heat conduction layer 250, a heat-dissipation member 300, and a connection pipe 410.

The package substrate 100 may be, for example, a printed circuit board (PCB). The package substrate 100 may include metal patterns 101, vias VA, a first insulating pattern SR1, and a second insulating pattern SR2. Each of the metal patterns 101 and the vias VA may be formed of or include, for example, titanium (Ti), copper (Cu), nickel (Ni), or gold (Au). The package substrate 100 may include an insulating layer, and the insulating layer may include a glass fiber or a resin.

The package substrate 100 may include a plurality of first substrate pads PD1, which are disposed on a top surface of the package substrate 100, and a plurality of second substrate pads PD2, which are disposed on a bottom surface of the package substrate 100.

Outer connection terminals 110 may be disposed on the second substrate pads PD2, respectively. The outer connection terminals 110 may include solder balls or solder bumps. Depending on the kind and arrangement of the outer connection terminals 110, the semiconductor package may be classified into a ball grid array (BGA) structure, a fine ball-grid array (FBGA) structure, or a land grid array (LGA) structure. For example, the outer connection terminal 110 may include an alloy material including at least one of tin (Sn), silver (Ag), copper (Cu), nickel (Ni), bismuth (Bi), indium (In), antimony (Sb), or cerium (Ce).

The first and second insulating patterns SR1 and SR2 may be disposed on the bottom and top surfaces of the package substrate 100, respectively. Each of the first and second insulating patterns SR1 and SR2 may be provided to allow the first substrate pads PD1 and the second substrate pads PD2 to be exposed to the outside. For example, the first insulating patterns SR1 may be disposed between adjacent first substrate pads PD1 on the bottom surface of the package substrate 100, and the second insulating patterns SR2 may be disposed between adjacent second substrate pads PD2 on the top surface of the package substrate 100. The first and second insulating patterns SR1 and SR2 may include a solder resist.

The semiconductor chip 200 may be disposed on the package substrate 100. The semiconductor chip 200 may have four side surfaces 200s that are connected to each other. In an embodiment of the present inventive concept, the semiconductor chip 200 may be a logic chip or a memory chip. For example, the semiconductor chip 200 may be a central processing unit (CPU), a graphics processing unit (GPU), an application specific integrated circuit (ASIC) chip, a dynamic random access memory (DRAM) chip, a static random access memory (SRAM) chip, or a NAND FLASH memory chip. A plurality of chip pads CPD may be disposed on a bottom surface of the semiconductor chip 200.

Connection terminals 111 may be disposed between the semiconductor chip 200 and the package substrate 100. In an embodiment of the present inventive concept, a plurality of connection terminals 111 may be arranged in a first direction D1 and/or a second direction D2.

In the present specification, the first direction D1 may be defined as a direction that is parallel to the top surface of the package substrate 100. The second direction D2 may be defined as a direction that is parallel to the top surface of the package substrate 100 and is substantially perpendicular to the first direction D1. A third direction D3 may be defined as a direction that is substantially perpendicular to the top surface of the package substrate 100.

The connection terminals 111 may be interposed between the chip pads CPD and the second substrate pads PD2. For example, the connection terminals 111 may be in contact with the chip pads CPD and the second substrate pads PD2. The connection terminals 111 may be formed of or include substantially the same or similar metal material as the outer connection terminal 110. For example, the connection terminals 111 may include at least one of tin (Sn), bismuth (Bi), lead (Pb), silver (Ag), or alloys thereof.

An under-fill pattern UF may be provided between the package substrate 100 and the semiconductor chip 200. The under-fill pattern UF may fill a space between the package substrate 100 and the semiconductor chip 200 and may enclose a side surface of each of the connection terminals 111. The under-fill pattern UF may include, for example, an epoxy resin.

The adhesive pattern 120 may be disposed on an edge region of the package substrate 100. In an embodiment of the present inventive concept, a plurality of adhesive patterns 120 may be provided to be spaced apart from the semiconductor chip 200 in the first direction D1. The adhesive pattern 120 may be formed of or include at least one, for example, of epoxy, aluminum (AI), aluminum oxide (Al₂O₃), aluminum nitride (AlN), magnesium oxide (MgO), silicon carbide (SiC), or silicon (Si). The adhesive pattern 120 may be used to attach the heat-dissipation member 300 to the package substrate 100. The adhesive pattern 120 may be disposed between the heat-dissipation member 300 and the package substrate 100.

The heat conduction layer 250 may be disposed on a top surface of the semiconductor chip 200. The heat conduction layer 250 may include a thermal interface material (TIM). In an embodiment of the present inventive concept, the heat conduction layer 250 may be formed of or include at least one of aluminum (AI), aluminum oxide (Al₂O₃), aluminum nitride (AlN), magnesium oxide (MgO), silicon carbide (SiC), or silicon (Si).

The heat-dissipation member 300 may be disposed on the package substrate 100. The heat-dissipation member 300 may have a cavity CV. In the present specification, the cavity CV may be defined as an empty space that is formed between the package substrate 100 and the heat-dissipation member 300. The semiconductor chip 200 and the heat conduction layer 250 may be disposed in the cavity CV and on the package substrate 100.

The heat-dissipation member 300 may include a first region 300a and a second region 300b. The first region 300a may be disposed on the semiconductor chip 200. For example, the first region 300a may be a region that is overlapped with the semiconductor chip 200 in the third direction D3. The heat conduction layer 250 may be in contact with the first region 300a of the heat-dissipation member 300. The second region 300b of the heat-dissipation member 300 may be a region that is continuously connected to the first region 300a and is provided on the edge region of the package substrate 100. The second region 300b may be spaced apart from the semiconductor chip 200 in the first direction D1. The adhesive pattern 120 may be provided between the package substrate 100 and the second region 300b of the heat-dissipation member 300. The adhesive pattern 120 may be in contact with the second region 300b of the heat-dissipation member 300.

The first region 300a of the heat-dissipation member 300 may have a first thickness TH1. The second region 300b of the heat-dissipation member 300 may have a second thickness TH2. The second thickness TH2 may be larger than the first thickness TH1. In an embodiment of the present inventive concept, the first thickness TH1 may range from about 0.1 mm to about 0.3 mm. The second thickness TH2 may range from about 0.7 mm to about 1.2 mm.

The heat-dissipation member 300 may include a metal material with high thermal conductivity. The heat-dissipation member 300 may be formed of or include at least one of, for example, aluminum (AI) or copper (Cu).

The heat-dissipation member 300 may include a heat-dissipation pipe 400. In the present specification, the heat-dissipation pipe 400 may serve as the evaporator 400 that is described with reference to FIG. 1.

The heat-dissipation pipe 400 may be provided in the second region 300b of the heat-dissipation member 300. As shown in FIG. 2, the heat-dissipation pipe 400 may be disposed to extend along three of the four side surfaces 200s of the semiconductor chip 200.

For example, the heat-dissipation pipe 400 may include a body portion 400a, which has a shape of the letter ‘U’, and an injection portion 400b, which is connected to an end of the body portion 400a, when viewed in a plan view. The body portion 400a and the injection portion 400b may be connected to each other to form a single object.

The body portion 400a may be provided to at least partially enclose and/or at least partially surround the semiconductor chip 200. When viewed in a plan view, the heat-dissipation member 300 may have four sides, and the body portion 400a may be provided to be adjacent to three of the four sides of the heat-dissipation member 300. For example, the body portion 400a may extend along the three sides of the heat-dissipation member 300.

In an embodiment of the present inventive concept, a plurality of injection portions 400b may be provided to be spaced apart from each other in the first direction D1. The injection portion 400b may have a shape protruding from the body portion 400a.

A diameter DA of the heat-dissipation pipe 400 may be larger than the first thickness TH1 of the first region 300a. In an embodiment of the present inventive concept, the diameter DA of the heat-dissipation pipe 400 may range from about 0.6 mm to about 1 mm.

The heat-dissipation pipe 400 may be configured to allow the refrigerant 450 to pass therethrough. In an embodiment of the present inventive concept, the refrigerant 450 may include at least one of isobutane (C₄H₁₀) or tetrafluoroethane (CH₂FCF₃). The temperature of the refrigerant 450 may vary depending on the boiling points of its constituents and may be maintained in a specific temperature range. For example, the temperature of the refrigerant 450 may be maintained within a range of about −30° C. to about 20° C. The refrigerant 450 may be evaporated by heat energy that is generated from the semiconductor chip 200 so that the heat energy of the semiconductor chip 200 is reduced, and this may allow the heat-dissipation member 300 to function as a cooling element. In other words, the temperature of the semiconductor chip 200 may be reduced.

The connection pipe 410 may be connected to an end of the heat-dissipation pipe 400. For example, the connection pipe 410 may be connected to the injection portion 400b of the heat-dissipation pipe 400. The injection portion 400b may be provided between the connection pipe 410 and the body portion 400a. The connection pipe 410 may be configured to allow the refrigerant 450 to pass therethrough. In other words, the refrigerant 450 may be provided from the expansion valve 700 that is described with reference to FIG. 1 and may be transferred to the body portion 400a through the connection pipe 410 and the injection portion 400b.

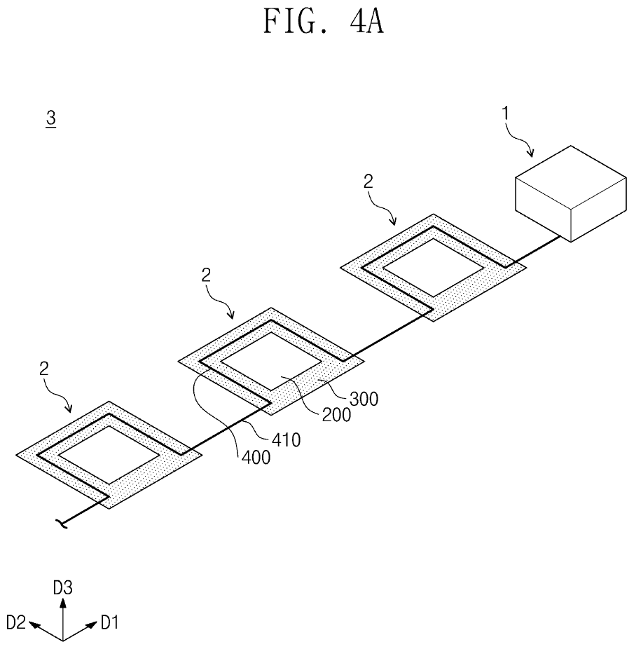

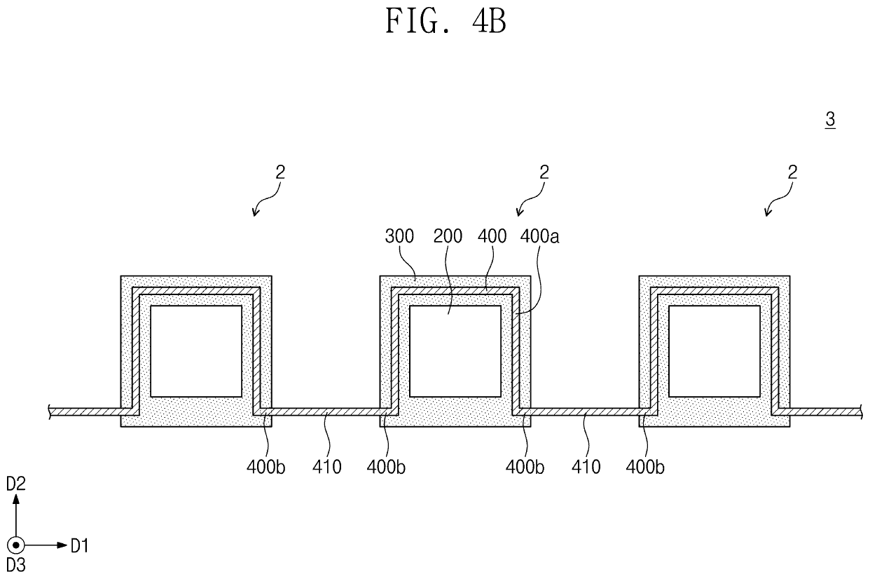

FIG. 4A is a perspective view illustrating a semiconductor package module according to an embodiment of the present inventive concept. FIG. 4B is a plan view illustrating a semiconductor package module according to an embodiment of the present inventive concept. For convenience in illustration, some elements may be omitted from the drawings.

Referring to FIGS. 4A and 4B, a semiconductor package module 3 may include a plurality of unit semiconductor packages 2. Each of the unit semiconductor packages 2 may include the semiconductor chip 200, the heat-dissipation member 300, and the connection pipe 410 described with reference to FIG. 3. In an embodiment of the present inventive concept, the semiconductor package module 3 may be provided for systems, such as data center servers and network servers, requiring a plurality of server racks.

Here, the unit semiconductor packages 2 may be connected to the refrigeration apparatus 1 described with reference to FIG. 1. The refrigeration apparatus 1 may include the compressor 500, the condenser 600, and the expansion valve 700 that are described with reference to FIG. 1. The refrigeration apparatus 1 may be connected to the heat-dissipation pipe 400 in the unit semiconductor packages 2 and may be used for cooling purposes.

The unit semiconductor packages 2 may be connected to each other through the connection pipe 410. The connection pipe 410 may be connected to an end of the heat-dissipation pipe 400. For example, the connection pipe 410 may connect ends of adjacent heat-dissipation pipes 400 of a pair of unit semiconductor packages 2 to each other. FIGS. 4A and 4B illustrate an example, in which the unit semiconductor packages 2 are connected to each other in series in the first direction D1, but the present inventive concept is not limited to this example. In the semiconductor package module 3, the placement and design of the unit semiconductor packages 2 may be variously combined and changed, and thus, the shape and the number of the connection pipe 410 may be changed.

According to an embodiment of the present inventive concept, a semiconductor package may include a heat-dissipation member, which is disposed on a semiconductor chip, and a heat-dissipation pipe, which is disposed in the heat-dissipation member. The heat-dissipation member may be thicker on an edge region of a package substrate than on the semiconductor chip. Here, the heat-dissipation pipe may be configured to allow a refrigerant to pass therethrough and may be provided on the edge region of the package substrate to at least partially enclose the semiconductor chip.

Thus, it may be possible to maintain a total thickness of the semiconductor package and to relatively increase a diameter of the heat-dissipation pipe in the heat-dissipation member. As a result, an amount of the refrigerant, which is supplied into the heat-dissipation pipe to reduce a heat energy that is generated from the semiconductor chip, may be sufficiently increased, and this may make it possible to maximize the heat-dissipation characteristics of the semiconductor package.

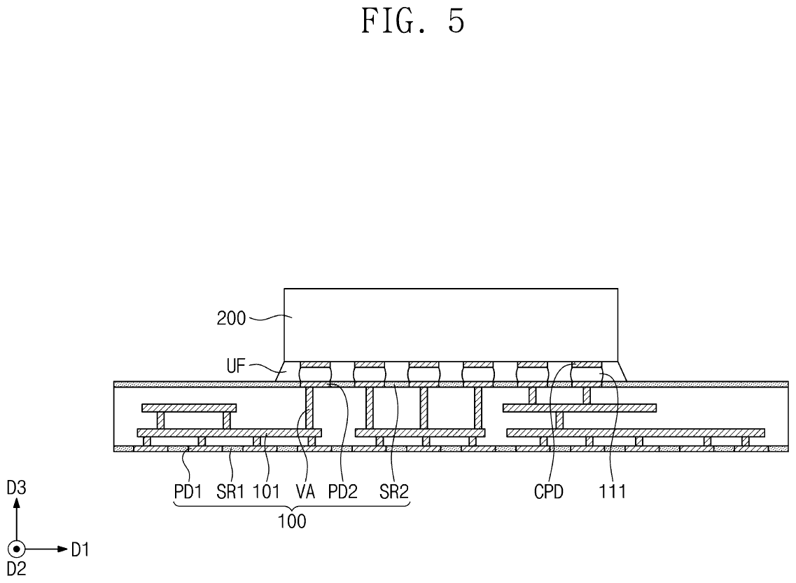

FIGS. 5, 6, and 7 are cross-sectional views illustrating a process of fabricating the unit semiconductor package 2, according to an embodiment of the present inventive concept.

Referring to FIG. 5, the package substrate 100 may be provided. The package substrate 100 may include the metal patterns 101, the vias VA, the first and second substrate pads PD1 and PD2, and the first and second insulating patterns SR1 and SR2.

The semiconductor chip 200 may be mounted on the package substrate 100. For example, the chip pads CPD may be formed on the bottom surface of the semiconductor chip 200. The chip pads CPD may be electrically connected to the second substrate pads PD2 through the connection terminals 111. In an embodiment of the present inventive concept, the semiconductor chip 200 may be mounted on the package substrate 100 in a flip chip manner. Thereafter, the under-fill pattern UF may be formed between the package substrate 100 and the semiconductor chip 200.

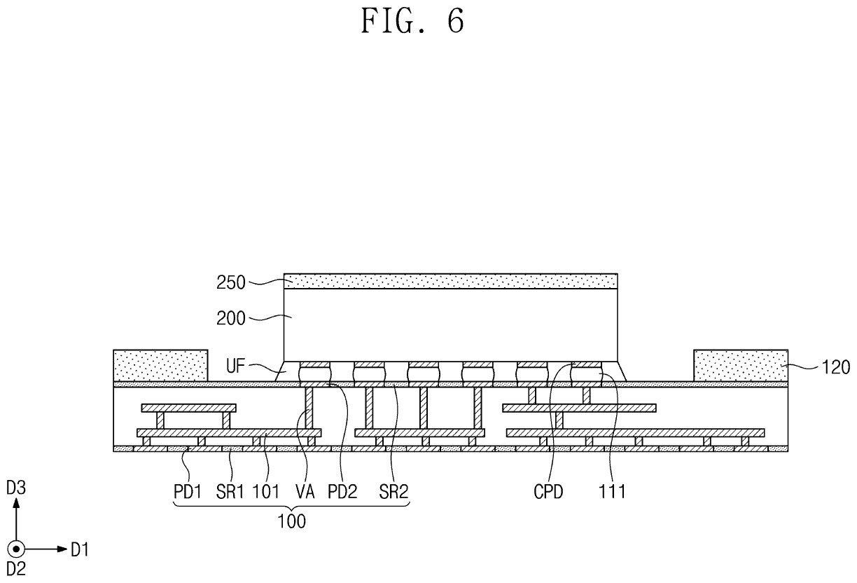

Referring to FIG. 6, the adhesive pattern 120 may be formed on the edge region of the package substrate 100. In an embodiment of the present inventive concept, the adhesive patterns 120 may be formed to be spaced apart from each other in the first direction D1, with the semiconductor chip 200 interposed therebetween. Thereafter, the heat conduction layer 250 may be formed on the top surface of the semiconductor chip 200.

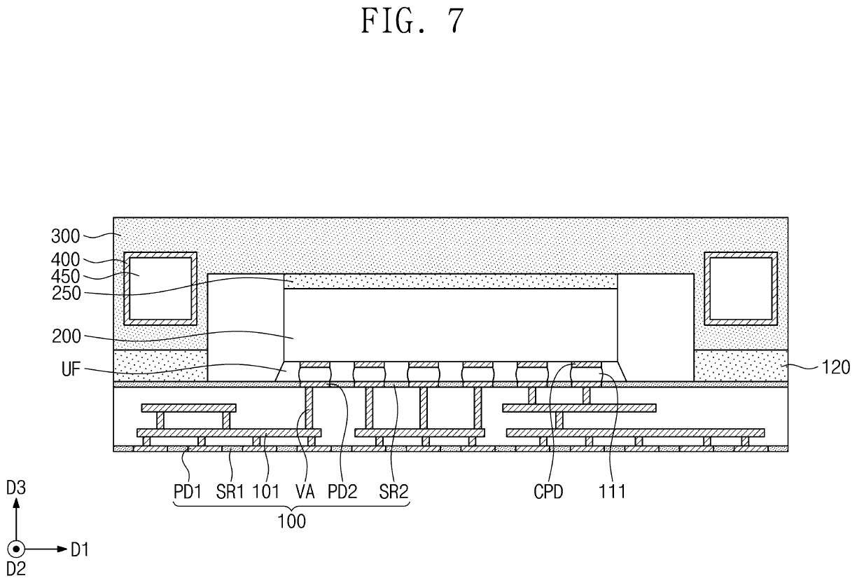

Referring to FIG. 7, the heat-dissipation member 300 may be provided on the semiconductor chip 200 and the adhesive pattern 120. For example, the heat-dissipation member 300 may be disposed on the heat conduction layer 250. The heat-dissipation member 300 may include the heat-dissipation pipe 400, which is configured to allow the refrigerant 450 to pass therethrough.

Here, the formation of the heat-dissipation pipe 400 may include forming a hole, in which the heat-dissipation pipe 400 will be inserted, in the heat-dissipation member 300, and inserting a metal pipe, which has a diameter smaller than that of the hole, into the hole. The formation of the heat-dissipation pipe 400 may further include injecting a high-temperature gas in the metal pipe to expand the metal pipe or to increase a diameter of the metal pipe to the diameter of the hole.

Thereafter, as described with reference to FIG. 3, the outer connection terminals 110 may be attached to the first substrate pads PD1 that are disposed on the bottom surface of the package substrate 100, and the unit semiconductor package 2 may be completed.

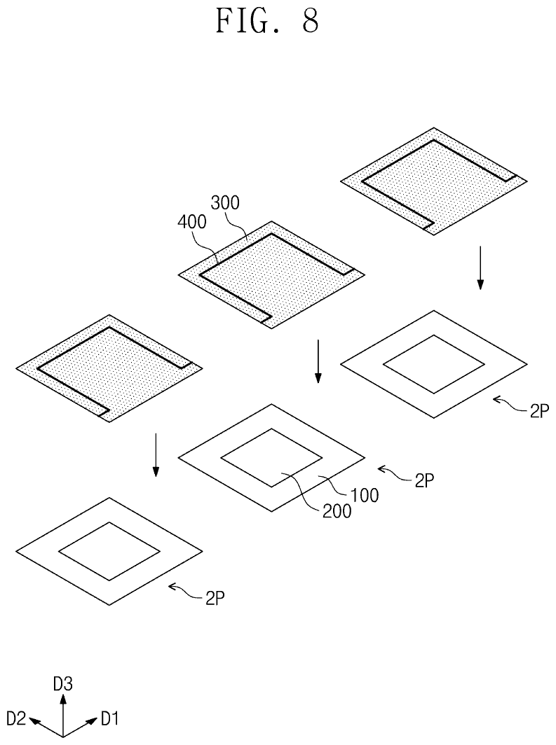

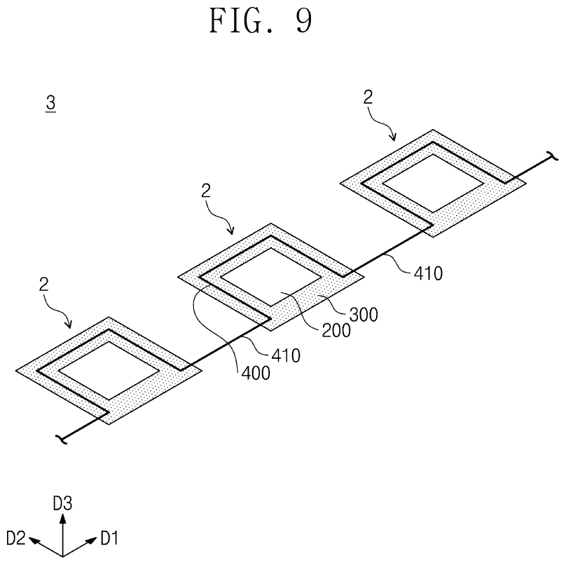

FIGS. 8 and 9 are cross-sectional views illustrating a process of fabricating a semiconductor package module, according to an embodiment of the present inventive concept. For example, FIGS. 8 and 9 illustrate a process of connecting the unit semiconductor packages 2 to each other to form the semiconductor package module 3, which is described with reference to FIGS. 4A and 4B. For convenience in illustration, some elements may be omitted from the drawings.

Referring to FIG. 8, a plurality of preliminary unit semiconductor packages 2P may be provided. Each of the preliminary unit semiconductor packages 2P may include the package substrate 100, the semiconductor chip 200, a heat conduction layer, and an adhesive pattern. Next, the heat-dissipation members 300 may be attached to the preliminary unit semiconductor packages 2P, respectively. Each of the heat-dissipation members 300 may include the heat-dissipation pipe 400 that is described with reference to FIG. 2.

Since the heat-dissipation member 300 is provided on the preliminary unit semiconductor package 2P, the unit semiconductor packages 2 may be formed.

Referring to FIG. 9, the unit semiconductor packages 2 may be connected to each other through the connection pipe 410. The connection pipe 410 may be connected to an ends of the heat-dissipation pipes 400, as described with reference to FIG. 2. In an embodiment of the present inventive concept, the connecting of the connection pipe 410 to the heat-dissipation pipe 400 may be executed by a flare connection process, a compression fitting process, a weld soldering process, and a compressive connection process. As a result of connecting the unit semiconductor packages 2 to each other through the connection pipe 410, the semiconductor package module 3 according to an embodiment of the present inventive concept may be completed.

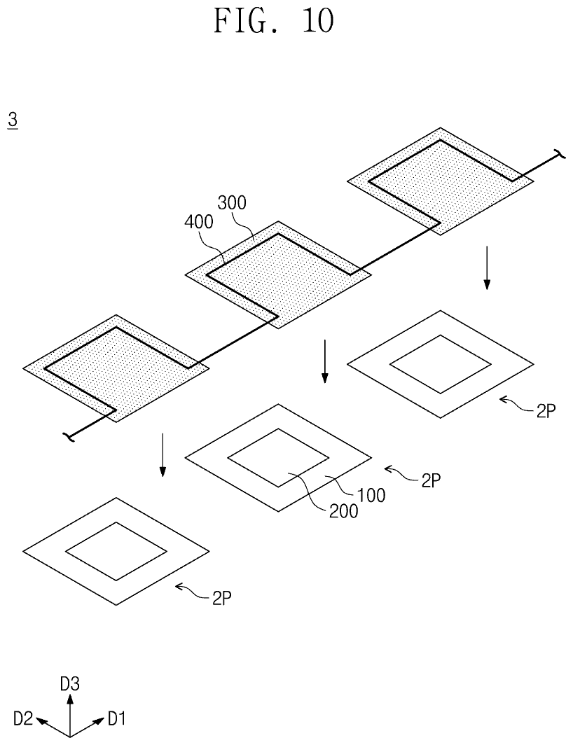

FIG. 10 is a cross-sectional view illustrating a process of fabricating a semiconductor package module, according to an embodiment of the present inventive concept.

Referring to FIGS. 8, 9, and 10, a plurality of heat-dissipation members 300 may be connected to each other through the connection pipe 410. The connection of the heat-dissipation members 300 may be executed by connecting the heat-dissipation pipe 400 to the connection pipe 410 through a method similar to that described with reference to FIG. 9. In an embodiment of the present inventive concept, a plurality of preliminary unit semiconductor packages 2P may be prepared. Each of the preliminary unit semiconductor package 2P may include the package substrate 100, the semiconductor chip 200, a heat conduction layer, and an adhesive pattern.

Next, since the heat-dissipation members 300, which are connected to each other through the connection pipe 410, are attached to the preliminary semiconductor packages 2P, respectively, the semiconductor package module 3 according to an embodiment of the present inventive concept may be completed.

According to an embodiment of the present inventive concept, a semiconductor package may include a heat-dissipation member on a semiconductor chip. The heat-dissipation member may include a heat-dissipation pipe, which is configured to allow a refrigerant to pass therethrough and is provided to at least partially enclose the semiconductor chip. Thus, when heat is generated from the semiconductor chip, the refrigerant that is in the heat-dissipation pipe may be evaporated, and a temperature of the semiconductor package may be lowered. As a result, the heat-dissipation characteristics of the semiconductor package may be improved, and it may be possible to prevent performance deterioration of the semiconductor chip and a reduction in the lifetime of the semiconductor chip.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package, comprising:
a package substrate;
a semiconductor chip disposed on the package substrate; and
a heat-dissipation member disposed on the package substrate,
wherein the heat-dissipation member comprises a heat-dissipation pipe,
the heat-dissipation member has a first region and a second region,
the first region is placed on the semiconductor chip,
the second region is placed on an edge region of the package substrate,
the first region has a first thickness,
the second region has a second thickness,
the second thickness is different from the first thickness, and
the heat-dissipation pipe is provided in the second region and faces at least one side surface of the semiconductor chip.

2. The semiconductor package of claim 1, wherein the first region is overlapped with the semiconductor chip in a first direction that is perpendicular to a top surface of the package substrate, and
the second region is spaced apart from the semiconductor chip in a second direction that is parallel to the top surface of the package substrate.

3. The semiconductor package of claim 1, further comprising an adhesive pattern disposed between the package substrate and the second region of the heat-dissipation member.

4. The semiconductor package of claim 3, wherein the adhesive pattern comprises at least one of epoxy, aluminum (AI), aluminum oxide (Al₂O₃), aluminum nitride (AlN), magnesium oxide (MgO), silicon carbide (SiC), or silicon (Si).

5. The semiconductor package of claim 1, further comprising a heat conduction layer disposed on the semiconductor chip,
wherein the heat conduction layer is in contact with the first region of the heat-dissipation member.

6. The semiconductor package of claim 1, wherein a diameter of the heat-dissipation pipe is larger than the first thickness.

7. The semiconductor package of claim 1, wherein a diameter of the heat-dissipation pipe ranges from about 0.6 mm to about 1 mm.

8. The semiconductor package of claim 1, wherein the first thickness ranges from about 0.1 mm to about 0.3 mm, and
the second thickness ranges from about 0.7 mm to about 1.2 mm.

9. The semiconductor package of claim 1, wherein the heat-dissipation pipe is configured to allow a refrigerant to pass therethrough, and
the refrigerant comprises at least one of isobutane (C₄H₁₀) or tetrafluoroethane (CH₂FCF₃).

10. The semiconductor package of claim 1, wherein the heat-dissipation pipe is configured to allow a refrigerant to pass therethrough, and
a temperature of the refrigerant ranges from about −30° C. to about 20° C.

11. A semiconductor package, comprising:
a package substrate;
a semiconductor chip disposed on the package substrate;
a heat-dissipation member disposed on the package substrate, wherein the heat-dissipation member has a cavity; and
a heat conduction layer disposed on the semiconductor chip,
wherein the semiconductor chip and the heat conduction layer are disposed in the cavity,
the heat-dissipation member comprises a heat-dissipation pipe,
when viewed in a plan view, the heat-dissipation pipe comprises:
a body portion having a ‘U’-shape; and
an injection portion connected to an end of the body portion,
wherein the body portion at least partially encloses the semiconductor chip.

12. The semiconductor package of claim 11, wherein the heat-dissipation member has four sides, when viewed in a plan view, and
the body portion extends along three of the four sides of the heat-dissipation member.

13. The semiconductor package of claim 11, further comprising a connection pipe connected to the injection portion,
wherein the injection portion is provided between the body portion and the connection pipe.

14. The semiconductor package of claim 11, wherein the injection portion protrudes from the body portion.

15. The semiconductor package of claim 11, wherein the injection portion comprises a plurality of injection portions, which are spaced apart from each other in a first direction that is parallel to a top surface of the package substrate.

16. The semiconductor package of claim 11, wherein the heat conduction layer comprises at least one of aluminum (AI), aluminum oxide (Al₂O₃), aluminum nitride (AlN), magnesium oxide (MgO), silicon carbide (SiC), or silicon (Si), and
the heat-dissipation member comprises at least one of aluminum (Al) or copper (Cu).

17. A semiconductor package module comprising:
a plurality of semiconductor packages and a connection pipe,
wherein each of the semiconductor packages comprises:
a package substrate;
a semiconductor chip disposed on the package substrate;
a heat-dissipation member disposed on the package substrate; and
a heat conduction layer disposed on the semiconductor chip,
wherein the heat-dissipation member comprises a heat-dissipation pipe provided in the heat-dissipation member,
the heat conduction layer is in contact with the heat-dissipation member,
the semiconductor chip has four side surfaces,
the heat-dissipation pipe is configured to allow a refrigerant to pass therethrough and to extend along three of the four side surfaces of the semiconductor chip,
the connection pipe is connected to an end of the heat-dissipation pipe, and
the semiconductor packages are connected to each other through the connection pipe.

18. The semiconductor package module of claim 17, further comprising a refrigeration apparatus connected to the semiconductor packages,
wherein the refrigeration apparatus comprises a condenser, an expansion valve, and a compressor.

19. The semiconductor package module of claim 17, wherein the plurality of semiconductor packages are connected to each other in series.

20. The semiconductor package module of claim 17, wherein a diameter of the heat-dissipation pipe ranges from about 0.6 mm to about 1 mm.
